(19) United States
(12) Patent Application Publication
(10) Pub. No.: US 2006/0097289 A1
(43) Pub. Date: May 11, 2006

(54) Method of forming ultra shallow junctions

(76) Inventor: Woo Sik Yoo, Palo Alto, CA (US)

Correspondence Address: MACPHERSON KWOK CHEN & HEID LLP, 1762 TECHNOLOGY DRIVE, SUITE 226, SAN JOSE, CA, 95110, US

(21) Appl. No.: 11/315,882

(22) Filed: Dec. 22, 2005

Related U.S. Application Data
(62) Division of application No. 10/916,182, filed on Aug. 10, 2004.

(51) Int. Cl. H01L 29/76; H01L 29/745

(52) U.S. Cl. 257/213

(57) ABSTRACT

A method of forming ultra shallow junctions in p-type devices uses aluminum ion to implant n-doped silicon, followed a low temperature anneal to activate and diffuse the aluminum. The use of aluminum provides numerous advantages over boron such as the ability to form shallower junctions, lower resistivity, and the ability to use lower temperature annealing.

### CROSS-REFERENCE TO RELATED APPLICATIONS

This application is a divisional of U.S. patent application Ser. No. 10/916,182, filed Aug. 10, 2004, which is incorporated herein by reference in its entirety for all purposes.

### BACKGROUND

1. Field of the Invention

This invention relates to methods of manufacturing semiconductor devices, and more particularly to forming ultra shallow junctions in such devices.

2. Related Art

As is well known, in a typical MOS transistor, source and drain regions of one conductivity type are formed in a body of opposite conductivity type. However, as photolithography and other semiconductor processing techniques improve, integrated circuits continue to decrease in size, e.g., down to deep sub-micron. As a result, the distance between source and drain regions (i.e., the channel) necessarily decreases as well. However, as the channel length decreases, short channel effects need to be minimized or eliminated in order for the device to operate correctly. One approach is to reduce the depth of the source and drain regions, i.e., the junction depth Xⱼ. For example, with a polysilicon gate width of 0.25 μm, the junction depth should be on the order of 800 Å or less.

Typical processes implant boron ions into regions of a silicon substrate to form shallow p-type source and drain regions. In general, boron ions are implanted with a chosen energy to control depth and a particular dosage to control the concentration. Since boron is an extremely light element, it is implanted with a very low energy, e.g., 1 KeV or less, in order to achieve a very shallow junction. A thermal anneal process (or dopant activation anneal) is performed to activate and diffuse the boron, as well as repair defects caused by the implantation process.

Unfortunately, such current processes for manufacturing devices with junction depths in the hundreds of angstroms have problems. For example, because the diffusion constant of boron of high, the boron quickly diffuses in the silicon substrate during an anneal, resulting in a deeper junction depth than desired. Further, arsenic or phosphorous ions are typically implanted for forming regions prior to the boron implantation. Because the influence of ion channel effect on boron ions is greater than that of arsenic or phosphorous (since the diffusion coefficient of boron is greater than that of arsenic or phosphorous), forming the p-type ultra shallow junction (USJ) with the source/drain and source/drain extension formation is very difficult. This, in turn, makes controlling the depth of the USJ difficult.

Another factor contributing to the rapid diffusion of boron difficulty in controlling junction depth is the existence of interstitial atoms of silicon in the substrate that result from the boron implantation. Boron implantation into a monocrystalline silicon layer causes implantation damage by generating interstitial atoms of silicon, i.e., atoms not in the crystal lattice but between lattice atoms. In other words, silicon atoms are displaced from the monocrystalline lattice and are sitting between silicon atoms in the monocrystalline lattice. During the anneal process, the high temperature causes boron to attach to these interstitial silicon atoms, resulting in a very rapid diffusion of the boron into the monocrystalline silicon layer (also known as transient enhanced diffusion (TED)). Thus, typically, when boron is implanted into monocrystalline silicon and then an anneal step is undertaken, the junction depth extends well beyond that desired, even when implanting boron ions at a very low energy and quickly annealed, such as by a flash or spike anneal in which the maximum temperature is maintained for a very short time (e.g., micro or nanoseconds).

Another disadvantage of using boron is shown when boron concentrations are increased during the implant. Previously, in order to achieve a lower resistivity (i.e., sheet resistance) in the implanted region, the amount of boron is increased so that there is a higher chance of having more electrically active boron in the silicon. However, once the solid solubility limits of boron are reached, increasing the boron has no effect on resistivity. In fact, adding boron past certain limits has undesirable effects. For example, additional dopant adversely increases the depth of the junction. Furthermore, annealing does not activate all the dopants. Thus, when more boron is added, there will be even more non-activated boron in the silicon. This can generate or cause crystal defects in the p-n junctions, resulting in leakage paths. Finally, ion implantation with boron can cause end-of-range damage at the interface, resulting in leakage and other undesirable characteristics. High temperature annealing is necessary for higher electrical activation of boron atoms. This causes additional dopant diffusion and junction depth increase.

Accordingly, it is desirable to have a method of forming ultra shallow junctions without the disadvantages discussed above associated with conventional techniques using boron and boron containing ion implantation.

### SUMMARY

In accordance with one aspect of the present invention, ultra shallow junctions are formed by using aluminum ions (Al⁺) (e.g., AlF₃, AlCl₃, etc.) for implanting p-type dopants into a substrate. In one embodiment, a p-type substrate is provided, an n-well is formed, such as by implantation with phosphorus (P⁺) or arsenic (As⁺) ions. Next, an implant step is performed using aluminum ions, followed by a low temperature anneal, such as a laser, flash, or spike anneal, to activate and diffuse the aluminum into the silicon. The resulting semiconductor device has a lightly doped ultra shallow junction with junction depth Xⱼ less than 1000 Å. By changing various parameters, such as the concentration of aluminum, the implant energy, and the anneal time, desired characteristics of the ultra shallow junction can be controlled.

Aluminum also provides other advantages, such as providing a junction that has good ohmic contact. Aluminum silicon has been used in the industry as material for ohmic contacts due to its low resistivity. Thus, ultra shallow junctions formed by implanting aluminum into silicon will also be of low resistance and a good ohmic contact. Changing the aluminum concentration modifies the resistivity of the junction. Furthermore, in mixing aluminum with silicon, the melting temperature is reduced as compared to silicon or aluminum alone. As a result, solubility of aluminum in silicon is higher at low temperatures, resulting in higher activation during the annealing step and less crystal defects.

Additional advantages include the ability to use a lower annealing temperature due to the high solid solubility of aluminum in silicon and the slow diffusion of aluminum in silicon. Slow diffusion, due in part to a larger molecular size than boron, prevents the junction from becoming too deep during annealing.

P-type dopants other than aluminum, such as gallium, indium, and thallium, may also be used to form the ultra shallow junction.

This invention will be more fully understood in light of the following detailed description taken together with the accompanying drawings.

### BRIEF DESCRIPTION OF THE DRAWINGS

FIGS. 1A-1F are process steps for forming an ultra shallow junction according to one embodiment; and

FIG. 2 is a plot of specific contact resistance as a function of doping level for alloyed contacts to silicon; and

FIG. 3 is a graph showing an aluminum silicon phase diagram.

Embodiments of the present invention and their advantages are best understood by referring to the detailed description that follows. It should be appreciated that like reference numerals are used to identify like elements illustrated in one or more of the figures.

### DETAILED DESCRIPTION

According to one aspect of the present invention, an ultra shallow junction (USJ) is formed in a semiconductor device by implanting an n-well with aluminum or gallium instead of boron, followed by a low temperature anneal, which allows a very shallow depth to be controlled and a high ohmic contact for the junction.

In one embodiment, a p-type transistor is formed with ultra shallow junctions of depth 1000 Å or less by implanting the n-well with aluminum, followed by a low temperature (e.g., 1000° C. or less) anneal, such as flash, spike, or regular furnace anneal. Because it is believed that aluminum has a high solubility in silicon, the annealing step will result in higher activation and thus lower occurrences of crystal defects. Furthermore, the resulting USJ has low resistivity since aluminum silicon has been used as an ohmic contact due to its low resistivity characteristic. The aluminum content in the silicon can be changed to modify the ohmic resistivity of the USJ to a desired value. Aluminum is used in one embodiment of the invention because when mixed with silicon, the melting temperature is lower than either silicon or aluminum alone, thereby increasing solubility.

A low temperature anneal is sufficient to activate the aluminum because the solid solubility of aluminum is believed to be high and reactions between silicon and aluminum. As a result, the aluminum does not diffuse quickly or deeply into the silicon, and the amount or concentration of aluminum in silicon can be controlled by the ion implantation, such as not exceeding certain eutectic temperatures.

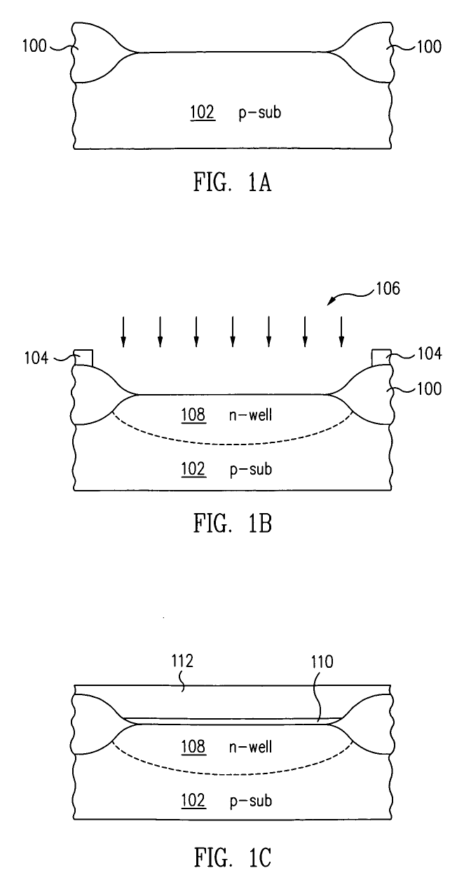

FIGS. 1A-1F show various processing steps according to one embodiment. In FIG. 1A, field oxide (FOX) regions 100 are formed on a silicon substrate or wafer 102 that has been lightly doped with p-type material. Field oxide regions 100 can be formed using any conventional methods. Next, a photoresist layer 104 is deposited over the substrate and patterned, according to conventional photolithography methods. After the photoresist is selectively removed, n-well dopants 106 are implanted to form an n-well 108, as shown in FIG. 1B. In FIG. 1C, a dielectric layer 110 is deposited over n-well 108 between field oxide regions 100, followed by a conductive material 112, such as polysilicon, deposited over dielectric layer 110. Conductive material 112 is then patterned and removed by conventional methods to form a gate electrode or polysilicon gate 114, as shown in FIG. 1D. In FIG. 1D, dielectric layer 110 is also patterned and etched to form thin gate oxide 116 between gate 114 and n-well 108. Note that field oxide regions 100 define outer edges of active regions to be formed, and polysilicon gate 114 defines corresponding inner edges.

Next, aluminum ions (Al⁺) 118 are implanted to form lightly doped regions 120 and 122 in n-well 108, as shown in FIG. 1E. Aluminum ions can be from a variety of sources, such as AlF₃, AlCl₃, etc. Aluminum ions 118 are applied at a dose within the range of 1E13 to 1E16 ions/cm² at an energy level of between 0.5 KeV and 50 KeV. The resulting structure is then annealed at a temperature less than approximately 1000° C., e.g., 800° C., for approximately 0.1 micro seconds up to 24 hours, depending on the process and device characteristics to form ultra shallow junctions 124 and 126, as shown in FIG. 1F. The annealing can be with a flash, laser, or spike anneal, as is known in the art. The semiconductor material is annealed to eliminate crystal defects in the diffused layers, since the semiconductor crystal lattice may have been damaged during the ion implantation process.

Annealing also activates the dopant (e.g., aluminum) atoms by putting them on substitutional sites, i.e., the aluminum ions “drop” into the crystal lattice sites to determine active junctions. During annealing, the aluminum diffuses in lightly doped regions 116 and 118 to form ultra shallow junctions (or lightly doped source and drain regions). Using the present invention, ultra shallow junctions can be formed having depths of between 10 Å and 1000 Å. Conventional processing then continues to form the transistor.

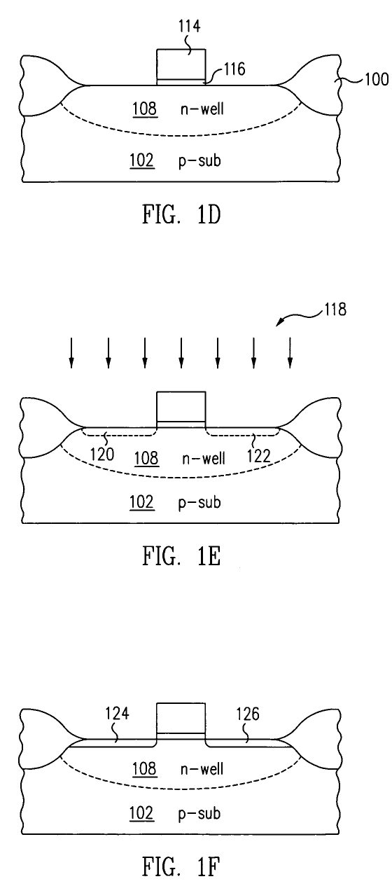

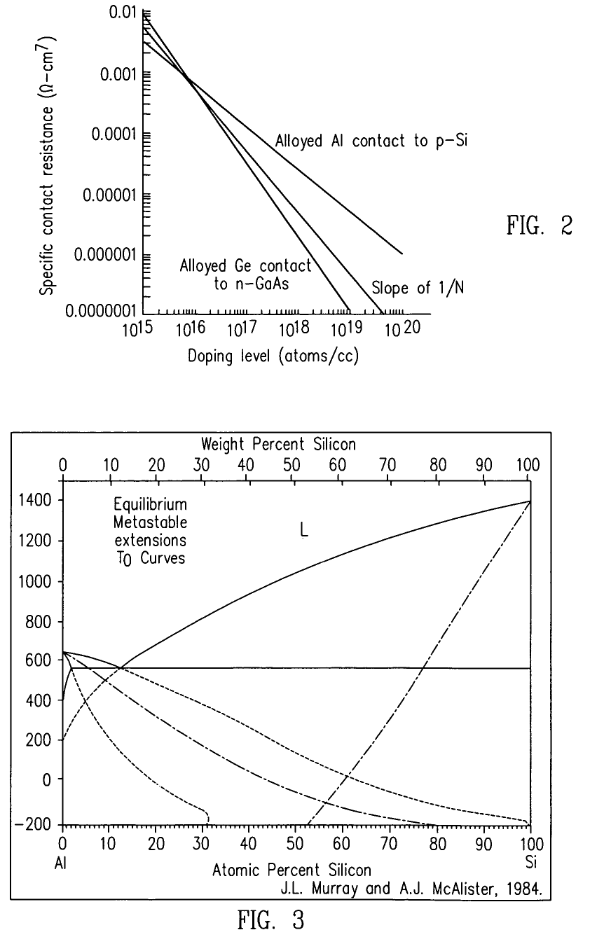

FIGS. 2 and 3 are plot showing different characteristics of aluminum and silicon, which can be used to aid in determining various process parameters for forming the USJ. FIG. 2 is a plot showing the relationship between specific contact resistance and doping level for alloyed contact to p-Si, and FIG. 3 is a plot showing an aluminum silicon phase diagram. FIGS. 2 and 3 are from “Semiconductor Integrated Circuit Processing Technology” by Runyan and Bean, 1990.

Aluminum is desirable as the p-type dopant for implanting to create ultra shallow junctions for a number of reasons. It is believed that aluminum solubility in silicon is much higher than people expect, as aluminum can be solved in silicon very easily and vice versa. Thus, silicon can be easily mixed with aluminum during the implant/anneal process since the resulting binary alloy Si—Al has a lower melting point than either silicon or aluminum alone. For example, silicon melts at approximately 1420° C. and aluminum melts at approximately 660° C. However, the melting point of Si—Al is approximately 577° C. A higher solid solubility of aluminum in silicon also results in a higher activation of the aluminum during the annealing. Consequently, the ultra shallow junction formed from implanting with aluminum has less crystal defects.

The percentage of aluminum in silicon can be adjusted, as needed, to achieve desired characteristics. For example, the percentage can range from 0.01 ppb to 100% to obtain a desired solid solubility, as shown in FIG. 3. Then, a low temperature anneal can be performed to activate and diffuse the aluminum, as described above. With high solid solubility and the reaction of silicon and aluminum, the annealing temperature does not have to be high, e.g., temperatures less than 1000° C. can be used. However, since the diffusion coefficient of aluminum in silicon is not very high and because the atomic size of aluminum is much greater than boron, aluminum does not move or diffuse very fast during the annealing. In other words, excessive diffusion during anneal, such as with boron, is not a concern with aluminum. As a result, USJs can be accurately formed with very small junctions depths Xⱼ. Also, the concentration of aluminum in silicon can be controlled by ion implantation, e.g., so that certain eutectic temperatures are not exceeded.

Another advantage of the present invention is that the implant energy can be changed to create a desired junction depth Xⱼ in the device, as shown in Fig. X. Further, since aluminum silicon has low resistivity and been used as ohmic contact material, electrical conductivity for the resulting USJ will desirably have a lower resistance. Thus, in addition to a junction having a shallow depth Xⱼ, the junction will also have good contact properties. The concentration of aluminum in silicon can be changed to modify the ohmic resistivity of the junction.

Embodiments described above illustrate but do not limit the invention. It should also be understood that numerous modifications and variations are possible in accordance with the principles of the present invention. For example, the above embodiments have described the use of aluminum in the formation of ultra shallow junctions for p-type devices. However, other p-type dopants may also be used, such as gallium, indium, and thallium. With indium and thallium, the atomic size is larger, and thus closer in size to silicon, resulting in dopant atoms that are harder to diffuse or move. Furthermore, the above description shows forming ultra shallow junctions (USJs) in an n-well. However, USJs can be formed in any suitable n-doped silicon body. Consequently, it is harder to move between lattice atoms and the depth of diffusion during anneal is smaller. Accordingly, the scope of the invention is defined only by the following claims.

What is claimed is:

1. A semiconductor device, comprising:
an n-type silicon layer; and
an aluminum doped ultra shallow junction.

2. The device of claim 1, further comprising a p-type substrate, wherein the n-type silicon layer is formed in the p-type substrate.

3. The device of claim 1, wherein the n-type silicon layer is an n-well.

4. The device of claim 1, wherein the ultra shallow junction has a junction depth Xⱼ of less than 1000 Å.

5. The device of claim 1, wherein the ultra shallow junction has a resistivity less than 1 Ωcm.

6. The device of claim 1, wherein the n-type silicon layer is doped with arsenic or phosphorous.

7. The device of claim 1, wherein the concentration of aluminum in the ultra shallow junction is between 1E16 and 1E22 atoms/cm³.
